(19) United States
(12) Patent Application Publication
(10) Pub. No.: US 2018/0279509 A1
(43) Pub. Date: Sep. 27, 2018

(54) PACKAGED GLYCOL RUN-AROUND COOLING AIR HANDLING UNIT FOR MULTI-STORY DATA CENTERS

(71) Applicant: REVOLVER 26 INVESTMENT CORPORATION, Phoenix, AZ (US)

(72) Inventors: Lindsey Leckelt, Sherwood Park (CA); Ryan Vetsch, Fort Saskatchewan (CA); Benoit Boudreau, Sherwood Park (CA)

(21) Appl. No.: 15/933,791

(22) Filed: Mar. 23, 2018

Related U.S. Application Data
(60) Provisional application No. 62/475,398, filed on Mar. 23, 2017.

(51) Int. Cl. H05K 7/20; F24F 5/00

(52) U.S. Cl. CPC H05K 7/20745; F24F 5/0046; F24F 2110/12; H05K 7/20827; H05K 7/20763

(57) ABSTRACT

The present invention pertains to Air Handling Units (AHUs) as a means of providing cooling in data centers containing heat generating equipment such as computer, server and/or electrical equipment, which AHUs utilize two (2) part cooling systems in a primary/scavenger arrangement. The two (2) part split cooling systems are comprised of a primary Computer Room Air Conditioning (CRAC) unit and a Scavenger Unit, both of which contain two (2) cooling systems. The two proposed cooling systems are:
Glycol run-around cooling
Direct-Expansion (DX) cooling

### FIELD OF THE INVENTION

The present invention relates in general to Air Handling Units (AHUs) using two (2) packaged cooling solutions in a primary/scavenger arrangement. The two proposed cooling systems are
Glycol run-around cooling
Direct-expansion (DX) cooling

When outside air ambient conditions are sufficiently cool (approximately up to 55° F.), a glycol run-around cooling system is designed to provide full cooling without any DX cooling system requirement. The glycol run-around cooling system draws cool outside air through a scavenger coil and the thus-chilled glycol is then pumped to a primary side cooling coil. When the outdoor air temperatures are moderate, the glycol run-around system acts as a “pre-cooling” system. At that time, the DX system shall be used as “trim cooling” to match the supply air temperature. The DX system may utilize variable speed compressors and multiple circuits in order to provide precise load matching while also providing high part-load efficiency across a wide range of speeds.

### BACKGROUND

Data centers are facilities which contain computer, server and/or electrical equipment which operate continuously and generate heat. Stringent conditions imposed by equipment also limit the amount of outside air intake to minimize air contaminants entering data center and air humidity changes. To maintain equipment in operation, cooling solutions are required to maintain optimal conditions for equipment (net ΔT of 25° F.). Such cooling solutions employ Air Handling Units to condition data center recirculation air.

A further requirement of cooling systems is the efficiency at which they condition air. Since cooling systems consume a fraction of total facility electricity consumption, their efficiency is a key issue for data centers and is measured using the Power Usage Effectiveness (PUE). The PUE accounts for the net energy consumption of the facility and the net power consumption of the IT equipment. A lower PUE value indicates a higher efficiency cooling system for a given data center.

Equipment is cooled by installing AHUs along the data center perimeter. A walking corridor situated between the mechanical space and the white space containing the IT equipment allows for a raised floor construction where supplied air from the AHUs reach the servers through perforations on the floor. Supply air passing through equipment is heated and rises to a return air plenum in the ceiling where it is extracted by supply fans and pulled back to the AHU for cooling.

Traditional AHUs cool data center space through an air-to-fluid heat exchange involving compressed refrigerant. Heat from recirculation air is transferred to the compressed refrigerant which acts as an intermediary cooling fluid that transports heat to be rejected to the atmosphere. This embodiment further requires a condensing unit, a rooftop structure, which rejects heat by drawing outside air to chill the refrigerant. The disadvantage this system carries lies on the large power consumption required by the compressor to circulate refrigerant resulting in a large and inefficient PUE.

An alternate system cools equipment by way of transferring heat to chilled water, which similarly acts as an intermediary cooling fluid to transport heat to the condensing section of the system and rejects heat to the atmosphere. Unlike the previous system, this embodiment is comprised of a water chiller unit alone installed on the rooftop of the data center. Fluid transport from internal building pipes to rooftop infrastructure requires significant power consumption by pump and compressor, thereby adding to the system's inefficiency. Additionally, the system employs two (2) cooling systems, water and refrigerant, to carry out cooling, which adds to the cost of operating two (2) systems.

An alternate embodiment involves what is colloquially called a heat wheel system. Such systems comprise some form of air-to-air heat exchanger, which air-to-air heat exchanger is mounted rotationally and in the form of a metal plate. The air-to-air heat exchanger is typically shaped in the form of a disk, which disk may optionally be perforated. This air-to-air heat exchanger operates by rotating between two different airstreams, transferring heat from data room recirculation air in one half of the wheel, to cool intake air at the other half of the wheel, thereby providing cooled air stream and removing heated air stream generated by, for example, electronic equipment. This system maintains the set temperature and humidity of supplied primary air. In addition, moisture transport between one air stream and another remains approximately equal, such that humidity is maintained at set optimal conditions. This system features a coupled unit design, whereby heat exchange occurs by passing air through the section of the unit protruding external to the unit, while simultaneously passing warm recirculation air on the internal section of the unit. Representative heat wheel systems are described in U.S. Pat. No. 7,753,766. A disadvantage of this design is the inherent leak between the mixing air streams. In addition, cooling capacity depends on the surface area available for heat exchange. The cooling for this system is restricted per linear foot or area it occupies. This proposes that leakage between air streams will increase proportionally as surface area increases, as well as unit construction cost. Since the heat wheel relies on outdoor air temperature for cooling, the system applies for climate with a yearly max temperature that is cooler than the data center design return temperature. Otherwise, a full DX cooling coil must be dispensed for cooling.

To maintain operational equipment, data center facilities require a cooling system which is compact and maximizes useable space for IT equipment while maintaining efficiency by minimizing energy consumption, Additionally, feasible cooling systems reduce the need for intermediary infrastructure, and increase heat exchange effectiveness by minimizing air stream leaking and potential unwanted airstream mixing. The full cooling capacity of the system must also be independent of outdoor weather conditions.

### OBJECTS OF THE INVENTION

An object of the present invention is an economical, compact cooling, system which is comprised of two (2) packaged components that meet data center conditions and maintain optimal cooling energy efficiency. The system efficiency is greater than conventional cooling systems since the invention incorporates free cooling methods to condition air, there by minimizing power consumption of the AHU. Unlike conventional free cooling systems, the invention is not designed to have inherent leaks between mixing air streams that decreases heat exchange effectiveness. Additionally, efficiency is further increased by eliminating requirement for an intermediary cooling system which some cooling systems include. Further, the invention features a compact design. Since the system cooling capacity is minimally dependent on unit size, the building footprint and production cost are reduced. Moreover, the invention features a two (2) piece assembly, wherein the units are decoupled, allowing for various configurations to suit custom data center layouts. The versatility of the invention can accommodate larger cooling capacities by increasing coil capacity and/or using multiple units. The invention is modular and adaptable to custom data center building floor plans, and allows for more useable space to contain IT equipment.

The invention employs in-factory manufacturing and assembly to ensure quality control and repeatability. In addition, the assembly line production of this system facilitates rapid deployment of units.

### SUMMARY OF THE INVENTION

The present invention relates to a two (2) part split cooling system advantageously comprising a primary Computer Room Air Conditioning (CRAC) unit and a scavenger unit, wherein the primary CRAC comprises a glycol run-around cooling system and direct-expansion (DX) cooling coil in a primary/scavenger arrangement, such that, when outside air ambient conditions are sufficiently cool (approximately up to 55° F.), the glycol run-around cooling coil system is disposed to provide full recirculation cooling without requiring DX cooling system assist, the glycol run-around cooling system being disposed to draw cool outside air through a scavenger coil thereby chilling glycol comprised within the system and whereby the thus-chilled glycol is then pumped to a primary side cooling coil, such two (2) part split cooling system further comprising a direct-expansion (DX) cooling system, which DX cooling system is disposed to operate when outdoor air temperatures are moderate, whereby the glycol run-around system is then designed to operate as a “pre-cooling” system, and whereby the DX system is then designed to operate as “trim cooling” to match the supply air temperature, the DX system optionally utilizing variable speed compressors and multiple circuits in order to provide precise load matching while also providing high part-load efficiency across a wide range of speeds.

A further aspect of the two (2) part split cooling system is that the primary CRAC unit glycol run-around cooling system operates such that at sufficiently cool ambient outside air conditions (approximately up to 55° F.), full recirculation cooling is provided by the glycol run-around system.

A further aspect of the two (2) part split cooling system is that the primary CRAC unit also includes a direct expansion (DX) cooling system sized for full cooling capacity, which DX cooling system operates such that under moderately cool outside air conditions, the system uses the glycol run-around system as “pre-cooling” and employs a DX cooling coil to provide “trim cooling” to match supply air temperature.

A further aspect of the two (2) part split cooling system is that the scavenger unit contains a glycol heat-rejection coil which rejects heat transferred from data center recirculation air to the glycol system.

A further aspect of the two (2) part split cooling system is that the scavenger unit includes a condenser coil section which rejects heat from the DX cooling system to the environment.

A further aspect of the two (2) part split cooling system is that the scavenger unit features a recessed panel which contains a glycol pump, DX compressor, and auxiliary equipment necessary for cooling system operation.

A further aspect of the two (2) part split cooling, system is that the system is assembled in-factory and optionally configured as a split system, connected by external piping, and configured in multiple arrangements, or as a packaged assembly with internal factory-installed piping.

A further aspect of the two (2) part split cooling system is that the system is modular and adaptable to custom data center building floor plans, and allows for more useable space to contain IT equipment.

A further aspect of the invention is a method of modifying mechanics space air, such method utilizing the two (2) part split cooling system.

### BRIEF DESCRIPTION OF FIGURES

FIG. 1: is an elevation view of a typical arrangement of the primary CRAC unit installed in the mechanical space internal to the data center and scavenger unit installed on the rooftop external to the data center.

FIG. 2: is an elevation view of the two (2) part embodiment in a split-system arrangement comprising of the primary CRAC unit in the left and the scavenger unit in the right.

FIG. 3: is a perspective view of a typical two (2) part split-system arrangement which includes the primary CRAC unit and the scavenger unit on the right hand side.

FIG. 4: is an elevation view an optional arrangement of the embodiment as a packaged assembly.

FIG. 5: is a plan view of the packaged assembly option featuring a recessed enclosure that contains glycol and DX system accessories.

### DESCRIPTION

The present invention relates to a data center containing IT equipment which requires cooling systems using full recirculation cooling to allow a data center environmental operating envelope to be maintained within the most stringent ASHRAE data center environmental classes.

The claimed invention presents a two (2) part cooling solution as the means to cool recirculation air conditioned space. This two-part split system is comprised of the primary computer room air conditioning (CRAC) unit and the decoupled scavenger unit.

The claimed invention comprises a two (2) part cooling system comprised of a primary Computer Room Air Condition (CRAC) unit and a Scavenger Unit. The cooling system employs:
Glycol run-around cooling
DX cooling

When ambient outside air conditions are sufficiently cool (approximately up to 55° F.), the system employs a glycol run-around cooling coil system to provide full air cooling without DX cooling system assist. The glycol run-around cooling system is disposed to draw cool outside air through a scavenger coil thereby chilling glycol comprised within the system and whereby the thus-chilled glycol is then pumped to a primary side cooling coil, such air handling unit further comprising a direct-expansion (DX) cooling coil system, which DX cooling coil system is disposed to operate when outdoor air temperatures are moderate, whereby the glycol run-around system is then designed to operate as a “pre-cooling” system, and whereby the DX system is then designed to operate as “trim cooling” to match the supply air temperature, the DX system optionally utilizing variable speed compressors and multiple circuits in order to provide precise load matching while also providing high part-load efficiency across a wide range of speeds.

The system is comprised of a primary Computer Room Air Conditioning (CRAC) unit situated internal to the data center, and a Scavenger Unit external to the data center, which draws ambient outdoor air as the primary source of cooling. This arrangement employs glycol run-around and DX cooling systems.

The primary CRAC unit is comprised of a glycol run-around cooling coil and a DX cooling coil installed in series, each sized for full capacity. The primary CRAC unit draws air from return air extracted from the ceiling of an IT equipment white space, pulling air through MERV 8 filter banks installed upstream of the coils and supply air through wire mesh screen doors. Utilizing large size screen doors results in low air discharge velocity, minimizing space required between CRAC unit and IT equipment. The screen doors also offer accessibility to fan and motors and can be made secured by a lock.

The invention features a scavenger unit which is decoupled from the primary CRAC unit such that this enables multiple configurations. The scavenger unit is comprised of a glycol heat rejection coil and a DX condenser coil installed in series and both sized for full heat rejection capacity. In addition, the scavenger unit features an enclosure that contains a DX condenser compressor, glycol pump and other auxiliary coil accessories. Exhaust fans in the scavenger unit draw ambient outside air as a primary source of cooling.

The two (2) part cooling system offers a higher efficiency than conventional cooling systems as the input pump power required for a glycol run-around coil is less than the input power required for a compressor for conventional DX cooling systems.

The two (2) part cooling system is capable of matching cooling capacity of conventional cooling systems at a fraction of the load. In this way, cooling load is met while minimizing power consumption.

The glycol run-around cooling system is ineffective only under extreme temperatures, where outside air temperature is higher than data center return air temperature. Under the circumstance that, for instance, data center return air temperature is set at 100° F., (for example the Dallas, Texas region has an ASHRAE 20-year extreme temperature which is a few degrees above 100° F.), the system employs full DX compression cooling. This is similar to other conventional free cooling devices which require residual DX cooling assist under extreme weather conditions. Overall, the invention would have a smaller PUE and greater efficiency for the majority of the year.

The two (2) part cooling system is compact, and does not require a large budding footprint, thereby offering more useable space for data center equipment.

The piping required for both glycol run-around cooling and DX cooling systems are factory-installed and enclosed within the units, thereby limiting third-party contractor scope.

The two (2) piece packaged cooling system is versatile and offers any number of possible configurations in order to suit unique data center layouts. Unlike common cooling systems, the invention does not require a condensing unit installed in the data center roof. This allows for greater flexibility in arrangement, and facilitates accessibility to the scavenger unit.

The flexibility of the invention allows for increasing cooling capacity through reconfiguring system components. A large cooling capacity could for instance be achieved by sizing the glycol heat rejection and condensing coils at a larger capacity, and/or by modulating exhaust fan speed.

The invention may service a wide range of types of servers in comparison to conventional free cooling systems which require equipment to be built to withstand high temperature and humidity conditions. The invention thus allows for more opportunity to sell/rent data center space for a variety of servers.

The invention provides two (2) part packaged cooling option which incorporates both primary CRAC and scavenger unit in one assembly to offer the following benefits. This arrangement for instance decreases amount of eternal piping required by the system, as piping will be enclosed within the units and installed in-factory, limiting any third-party contractor scope. In addition, this decreases complexity of the system, easing site installation and maintenance. Providing piping enclosed within units decreases potential for leakage, which minimizes risk of damaging equipment.

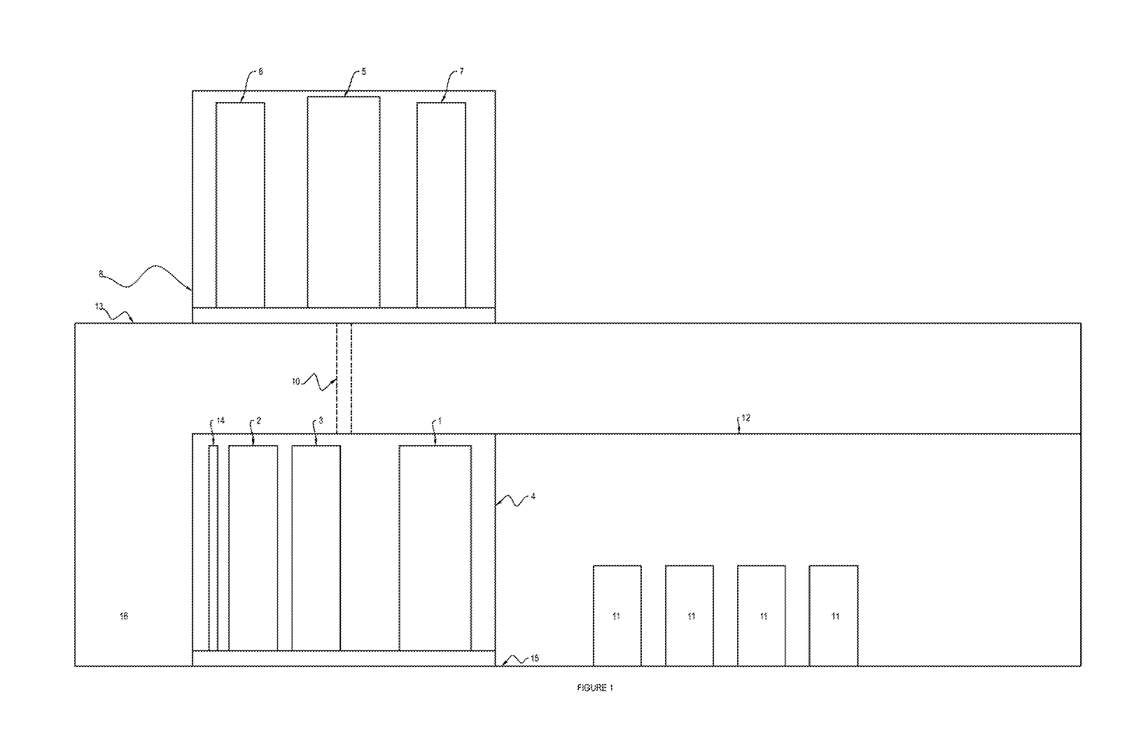

FIG. 1 illustrates a typical embodiment of the invention in a data center. The first aspect of the invention is a primary CRAC 4 unit installed in a corridor 16 running along a perimeter of the data center which hosts a CRAC gallery. This corridor optionally contains multiple CRAC units which serve to cool a white space 15 and equipment 11 using full air recirculation.

The primary CRAC unit 4 installed in a mechanical space of the data center comprises a glycol run-around cooling coil 2 and a DX cooling coil 3 installed in series. Recirculation air is drawn from a return air raised ceiling plenum 12 by a supply fan array 1. The air passes through a filter bank 14 installed upstream of the cooling coils.

During sufficiently cool ambient outside air conditions (approximately up to 55° F.), recirculation air in the data center rises to the ceiling 12 and is pulled into a primary CRAC unit 4 by supply fans 1 where heat is transferred to a glycol coil 2. Warm glycol fluid is pumped through piping 10 to glycol heat-rejection coils 6 in a scavenger unit 8. In the scavenger unit, cool outside air is extracted by exhaust fans 5 chilling the glycol. The chilled glycol is transported back to the primary CRAC unit 4 by way of piping 10 and a cooling cycle continues.

When outside air ambient conditions are moderately cool, the glycol system acts as a “pre-cooling” system. Recirculation air is drawn to a primary CRAC unit 4 by supply fans 1. Warm air passes through a filter bank 14 and is “pre-cooled” by a glycol run-around cooling coil 2. Remaining heat is transferred to a DX cooling coil 3 which acts as “trim cooling,” used to provide additional cooling to match supply air temperature at partial load of conventional compressed refrigerant systems. Warm glycol and compressed refrigerant are transported via piping 10 to a scavenger unit 8. Exhaust fans 5 draw in outdoor air to chill glycol and refrigerant is condensed in a condensing coil 7. Chilled glycol and refrigerant then circulate back to the primary CRAC unit 4.

The glycol run-around cooling system 4 is ineffective only under conditions where outdoor air temperature is higher than data center return air temperature. For instance, in cases where data center return air design temperature is 100° F. (for example the Virginia region has an ASHRAE 50-year extreme temperature of only a few degrees above 100° F.). During these residual times of the year, cooling is provided by a DX cooling system 3. Return air is cooled by compressed refrigerant in a DX cooling coil 3 of a primary CRAC unit 4. Warm refrigerant moves via piping 10 to a scavenger unit 8 where it passes through a compressor 9. In a similar manner as other free cooling systems, such as a heat wheel, only under such residual extreme weather temperatures would the system dispense full DX cooling 3.

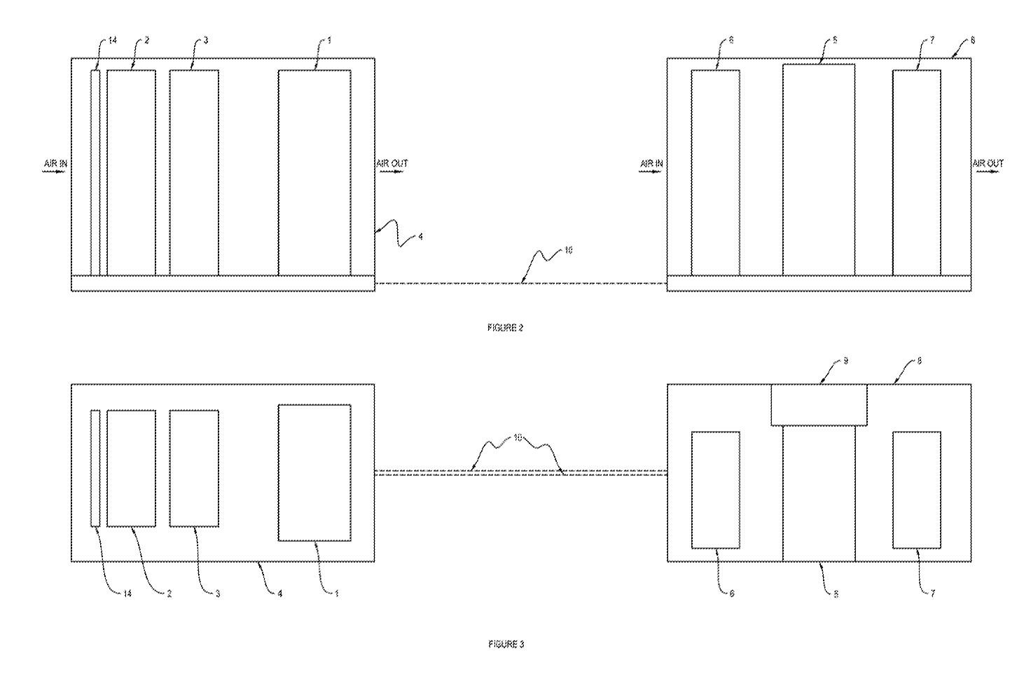

FIG. 2 depicts an alternate arrangement for a two (2) part split system. In comparison to conventional DX cooling systems, there is no requirement for the condensing section to be installed in the roof of a data center. A scavenger unit 8 may be arranged in multiple ways to intake ambient outdoor air through building ductwork. A supply fan array 1 draws in data center recirculation air into a primary CRAC unit 4 where air passes first through a filter bank 14 before air is cooled. Glycol and compressed refrigerant make their way to a scavenger unit 8 through external piping 10, where an exhaust fan array 5 pulls outside air directly or through an air chase to chill fluid.

FIG. 3 illustrates a corresponding plan view of an embodiment. Recirculation air is pulled into a primary CRAC unit 4 through a supply fan array 1. Air passes through a filter bank 14 before it is cooled through glycol run-around cooling 2 and/or DX cooling coil 3, depending on the outside air conditions and cooling requirement. Warm glycol and refrigerant are transported through external piping 10 to a scavenger unit 8. To reject heat from the system, an exhaust fan array 5 draws ambient outdoor air over glycol heat rejection coils 6 and condenser coils 7. Pump, compressor and auxiliary coil accessories are conveniently contained in a recessed enclosure 9, providing easy access for maintenance.

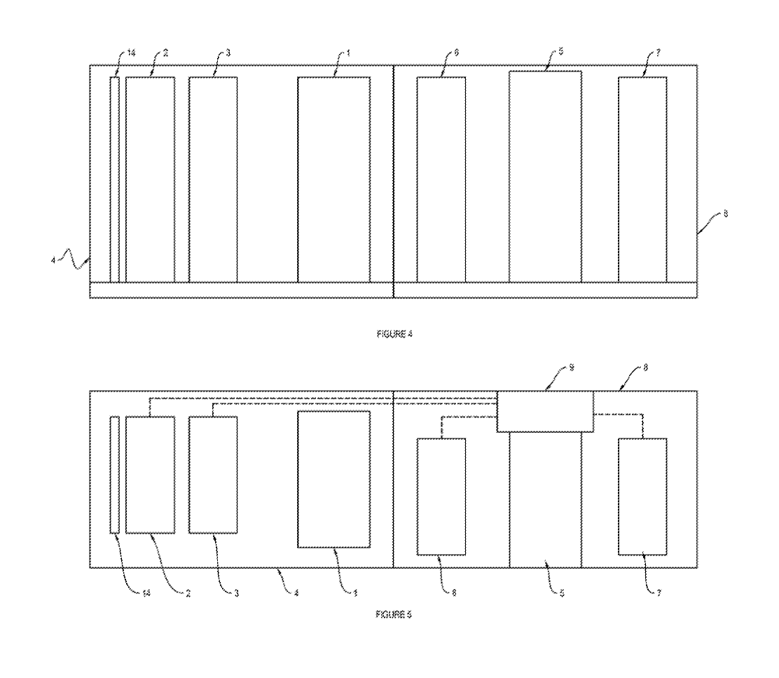

FIG. 4 depicts an alternate arrangement of the invention. In this case, a two (2) part system is manufactured as a packaged assembly. This embodiment may be installed external to a data center, where recirculation air and outdoor air circulate through separate ducts. Return air from a data center is pulled by a supply fan array 1 to a primary CRAC unit 4 through building ductwork, where it passes through a filter bank 14 before it is cooled via glycol run-around cooling coils 2 and/or DX cooling coils 3, depending on ambient outdoor air, temperature and cooling required. Supply air leaves the primary CRAC unit 4 through separate ductwork. Internal piping within such packaged embodiment transports fluid from a primary CRAC section 4 to a scavenger unit 8. An exhaust fan array 5 pulls outside air through an air chase to pass through a glycol heat-rejection coil and condenser coils, chilling glycol and compressed refrigerant in the process. An advantage to this arrangement is the utilization of factory-installed piping contained within the package assembly which minimizes third-party contractor scope for piping connections. This eases unit installation and maintenance while decreasing risks associated with potential system leakage.

The glycol run-around cooling coil component of the system increases efficiency by employing free cooling. The system uses ambient outside air as the primary source of cooling and uses a pump to transport fluid between primary CRAC unit and scavenger unit. Since the glycol pump requires less power than conventional DX compressors, electrical consumption is minimized. During cases when DX cooling is required to match supply air temperature, compressor input power is at a fraction of the energy required by traditional DX cooling systems, hence energy consumption is still minimized. Since the glycol cooling system functions for the majority of the year, the invention reduces power consumption of traditional DX cooling systems, lowering overall PUE and increasing efficiency while matching supply air conditions.

Further, glycol run-around cooling systems employ free cooling with minimal limitations on the climate of the facility. In comparison to air-to-air heat exchangers or other free cooling systems, the invention is not restricted to cool and relatively dry conditions. Additionally, the invention eliminates unwanted mixing of air streams which some free cooling systems exhibit since recirculation air and outside air streams are kept separate.

An increase in cooling capacity may be achieved through the use of multiple units. The invention incorporates a flexible design allowing further modification. A large cooling capacity can also perhaps be achieved by sizing the glycol heat rejection 6 and condensing coils 7 at a larger capacity to increase heat transfer. This maintains the compact size of the primary CRAC unit 4 which maximizes useable data center space, while providing a larger cooling capacity.

The decoupling of the scavenger unit from the CRAC unit offers flexibility for the design to be configured in multiple ways. For instance, while the invention does not require raised floor distribution, as is common in traditional data center cooling systems, it is an option that the invention can be adapted to fit.

The invention pertains to the use of a two (2) part split system to provide full recirculation air cooling in a data center which contains heat generating equipment. This system is comprised of a primary CRAC unit and a scavenger unit. Under sufficiently cool conditions, the glycol run-around cooling system provides free cooling, while moderate conditions call for DX cooling system to provide additional cooling to match supply air conditions. This system allows for precise load matching of data center design temperature at part-load conditions, optimizing the efficiency of the cooling system

The present invention is not to be limited in scope by the specific embodiments described herein. Indeed, various modifications of the invention in addition to those described herein will become apparent to those skilled in the art from the foregoing description. Such modifications are intended to fall within the scope of the appended claims.

All patents, applications, publications, test methods, literature, and other materials cited herein are hereby incorporated by reference.

1. A two (2) part split cooling system advantageously comprising a primary Computer Room Air Conditioning (CRAC) unit and a scavenger unit, wherein the primary CRAC comprises a glycol run-around cooling system and direct-expansion (DX) cooling coil in a primary/scavenger arrangement, such that, when outside air ambient conditions are sufficiently cool (approximately up to 55° F.), the glycol run-around cooling coil system is disposed to provide full recirculation cooling without requiring DX cooling system assist, the glycol run-around cooling system being disposed to draw cool outside air through a scavenger coil thereby chilling glycol comprised within the system and whereby the thus-chilled glycol is then pumped to a primary side cooling coil, such two (2) part split cooling system further comprising a direct-expansion (DX) cooling system, which DX cooling system is disposed to operate when outdoor air temperatures are moderate, whereby the glycol run-around system is then designed to operate as a “pre-cooling” system, and whereby the DX system is then designed to operate as “trim cooling” to match the supply air temperature, the DX system optionally utilizing variable speed compressors and multiple circuits in order to provide precise load matching while also providing high part-load efficiency across a wide range of speeds.

2. The two (2) part split cooling system of claim 1, wherein the primary CRAC unit glycol run-around cooling system operates such that at sufficiently cool ambient outside air conditions (approximately up to 55° F.), full recirculation cooling is provided by the glycol run-around system.

3. The two (2) part split cooling system of claim 1, wherein the primary CRAC unit also includes a direct expansion (DX) cooling system sized for full cooling capacity, which DX cooling system operates such that under moderately cool outside air conditions, the system uses the glycol run-around system as “pre-cooling” and employs a DX cooling coil to provide “trim cooling” to match supply air temperature.

4. The two (2) part split cooling system of claim 1, wherein the scavenger unit contains a glycol heat-rejection coil which rejects heat transferred from data center recirculation air to the glycol system.

5. The two (2) part split cooling system of claim 1, wherein the scavenger unit includes a condenser coil section which rejects heat from the DX cooling system to the environment.

6. The two (2) part split cooling system of claim 1, wherein the scavenger unit features a recessed panel which contains a glycol pump, DX compressor, and auxiliary equipment necessary for cooling system operation.

7. The two (2) part split cooling system of claim 1, which is assembled in-factory and optionally configured as a split system, connected by external piping, and configured in multiple arrangements, or as a packaged assembly with internal factory-installed piping.

8. The two (2) part split cooling system of claim 1, which is modular and adaptable to custom data center building floor plans, and allows for more useable space to contain IT equipment.

9. A method of modifying mechanical space air, such method utilizing the two (2) part split cooling system of claim 1.
